(19) United States
(12) Patent Application Publication
(10) Pub. No.: US 2026/0324123 A1
(43) Pub. Date: Oct. 15, 2026

(54) TUNNEL OXIDE PASSIVATED CONTACT SOLAR CELL AND FABRICATION METHOD THEREOF

(71) Applicant: TSEC Corporation, New Taipei City (TW)

(72) Inventors: Li-Guo Wu, New Taipei City (TW); Wei-Lo Chueh, Hsinchu County (TW); Shih-Chieh Lin, Hsinchu County (TW); Cheng-Yeh Yu, Hsinchu County (TW)

(73) Assignee: TSEC Corporation, New Taipei City (TW)

(21) Appl. No.: 19/439,427

(22) Filed: Jan. 4, 2026

(30) Foreign Application Priority Data
Apr. 15, 2025 (TW) 114114131

(51) Int. Cl. H10F 77/1223; H10F 71/00; H10F 77/20; H10F 77/30

(52) U.S. Cl. CPC H10F 77/1223; H10F 71/129; H10F 71/134; H10F 77/211; H10F 77/315

(57) ABSTRACT

A tunnel oxide passivated contact solar cell includes a substrate; an emitter layer disposed on the front side of the substrate; a front passivation layer disposed on the emitter layer; a front anti-reflection layer disposed on the front passivation layer; a front metal electrode passing through the front anti-reflection layer and the front passivation layer, contacting the emitter layer; a tunnel oxide layer disposed on the rear side of the substrate; a laser-activated doped semiconductor layer disposed on the tunnel oxide layer; a rear anti-reflection layer disposed on the laser-activated doped semiconductor layer; and a rear metal electrode passing through the rear anti-reflection layer, directly contacting the laser-activated doped semiconductor layer.

### BACKGROUND OF THE INVENTION

### 1. Field of the Invention

The present invention relates to the field of solar cell technology, and more particularly to an improved tunnel oxide passivated contact (TOPCon) solar cell structure and its fabrication method.

### 2. Description of the Prior Art

A TOPCon solar cell is an advanced solar cell technology that utilizes an n-type silicon base to enhance efficiency and performance. The fabrication steps include preparing an ultra-thin silicon oxide layer on the rear surface of the substrate, followed by depositing an n-type doped silicon layer. These two layers collectively form the passivated contact structure.

The passivation performance of the TOPCon solar cell’s rear surface is activated through a thermal annealing process. During this thermal annealing, the crystallinity of the N-type doped silicon layer changes, undergoing recrystallization from a mixed microcrystalline and amorphous phase to a polycrystalline phase. This structure effectively reduces carrier recombination caused by defects on the silicon wafer surface.

However, the N-type doped silicon layer in TOPCon cells has a single resistivity value, lacking localized low-resistivity regions. This results in the inability to achieve lower contact resistance, consequently impacting the cell efficiency. Furthermore, activating the N-type doped silicon layer requires a high-temperature annealing process, which involves long process times and high costs.

### SUMMARY OF THE INVENTION

It is an objective of the present invention to provide an improved tunnel oxide passivated contact solar cell structure and its fabrication method, in order to overcome the deficiencies and drawbacks of the prior art.

One aspect of the invention provides a tunnel oxide passivated contact solar cell including a substrate having a front side and a rear side; an emitter layer disposed on the front side of the substrate; a front passivation layer disposed on the emitter layer; a front anti-reflection layer disposed on the front passivation layer; a front metal electrode penetrating through the front anti-reflection layer and the front passivation layer, contacting the emitter layer; a tunnel oxide layer disposed on the rear side of the substrate; a laser-activated doped semiconductor layer disposed on the tunnel oxide layer; a rear anti-reflection layer disposed on the laser-activated doped semiconductor layer; and a rear metal electrode penetrating through the rear anti-reflection layer, directly contacting the laser-activated doped semiconductor layer.

According to some embodiments of the invention, the laser-activated doped semiconductor layer comprises at least one patterned low-resistivity region, and the at least one patterned low-resistivity region is disposed directly under the rear metal electrode.

According to some embodiments of the invention, the at least one patterned low-resistivity region is a laser-activated patterned region.

According to some embodiments of the invention, the laser-activated doped semiconductor layer further comprises at least one non-laser-activated region adjacent to the laser-activated patterned region, and a resistivity value of the laser-activated patterned region is lower than a resistivity value of the at least one non-laser-activated region.

According to some embodiments of the invention, the substrate comprises a P-type silicon substrate or an N-type silicon substrate.

According to some embodiments of the invention, the emitter layer comprises a boron-doped silicon layer or a phosphorus-doped silicon layer.

According to some embodiments of the invention, the tunnel oxide layer comprises silicon dioxide.

According to some embodiments of the invention, the entire laser-activated doped semiconductor layer is a laser-activated low-resistivity layer.

According to some embodiments of the invention, the laser-activated doped semiconductor layer comprises an N-type polycrystalline silicon layer.

According to some embodiments of the invention, the front metal electrode and the rear metal electrode comprise aluminum, silver, or an alloy thereof.

Another aspect of the invention provides a method for fabricating a tunnel oxide passivated contact solar cell. A substrate having a front side and a rear side is provided. An emitter layer is formed on the front side of the substrate. A tunnel oxide layer is formed on the rear side of the substrate. A doped semiconductor layer is formed on the tunnel oxide layer. A laser activation treatment is performed on the doped semiconductor layer. A front passivation layer is formed on the emitter layer. A front anti-reflection layer is formed on the front passivation layer. A rear anti-reflection layer is formed on the doped semiconductor layer. A front metal electrode is then formed. The front metal electrode penetrates through the front anti-reflection layer and the front passivation layer, contacting the emitter layer. A rear metal electrode is formed. The rear metal electrode penetrates through the rear anti-reflection layer, directly contacting the doped semiconductor layer.

According to some embodiments of the invention, the step of performing the laser activation treatment on the doped semiconductor layer comprises forming at least one patterned low-resistivity region in the doped semiconductor layer.

According to some embodiments of the invention, the at least one patterned low-resistivity region is only formed directly under the rear metal electrode, and wherein the doped semiconductor layer further comprises at least one non-laser-activated region adjacent to the at least one patterned low-resistivity region, and a resistivity value of the at least one patterned low-resistivity region is lower than a resistivity value of the at least one non-laser-activated region.

According to some embodiments of the invention, the step of performing the laser activation treatment on the doped semiconductor layer comprises converting the entire doped semiconductor layer into a low-resistivity layer using a laser.

According to some embodiments of the invention, the method further comprises a thermal annealing process after performing the laser activation treatment on the doped semiconductor layer.

According to some embodiments of the invention, the doped semiconductor layer comprises a polycrystalline semiconductor layer, a microcrystalline semiconductor layer, or an amorphous semiconductor layer.

According to some embodiments of the invention, the substrate comprises a P-type silicon substrate or an N-type silicon substrate.

According to some embodiments of the invention, the emitter layer comprises a boron-doped silicon layer or a phosphorus-doped silicon layer.

According to some embodiments of the invention, the tunnel oxide layer comprises silicon dioxide.

According to some embodiments of the invention, the front metal electrode and the rear metal electrode comprise aluminum, silver, or an alloy thereof.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 - 5 are schematic diagrams illustrating a method for fabricating a tunnel oxide passivated contact solar cell according to an embodiment of the present invention.

FIGS. 6 - 10 are schematic diagrams illustrating a method for fabricating a tunnel oxide passivated contact solar cell according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

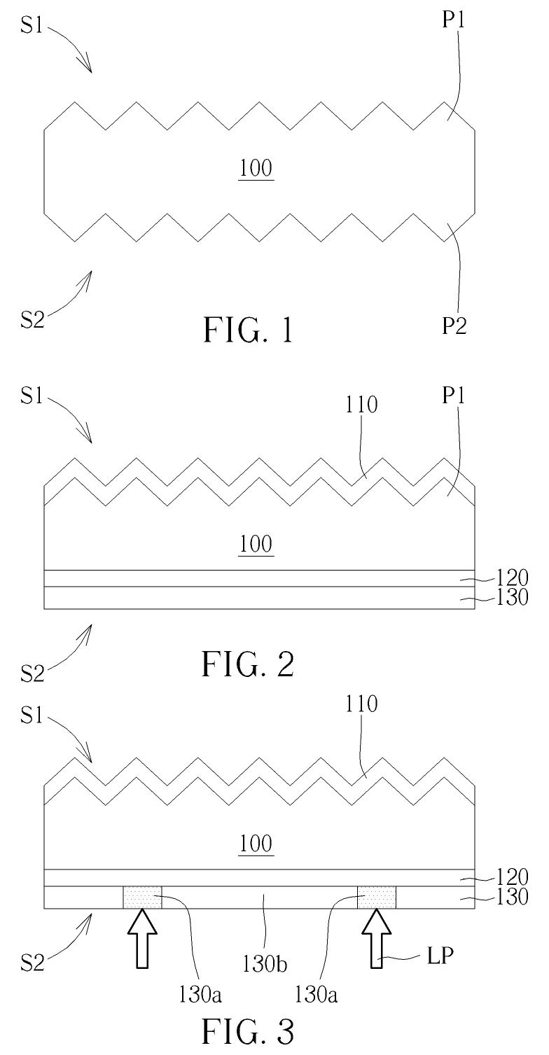

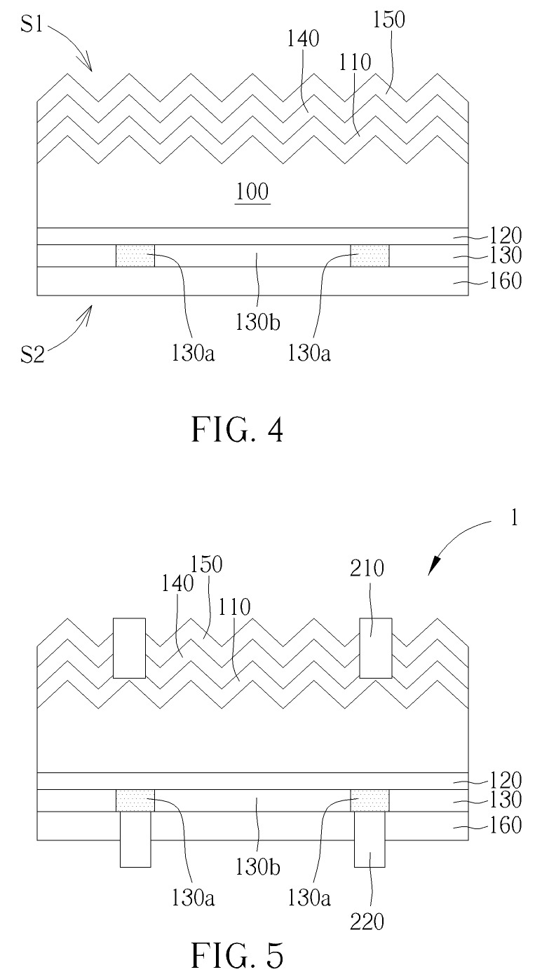

Please refer to FIGS. 1 - 5, which are schematic diagrams illustrating a method for fabricating a tunnel oxide passivated contact solar cell according to an embodiment of the present invention. As shown in FIG. 1, a substrate 100, such as a P-type silicon substrate or an N-type silicon substrate, is first provided. The wafer surface is then cleaned, and texturized structures P1 and P2 are respectively formed on a front side S1 and a rear side S2 of the substrate 100.

As shown in FIG. 2, a boron diffusion process is performed to form an emitter layer 110 on the front side S1 of the substrate 100 (e.g., an N-type silicon substrate). According to an embodiment of the present invention, the emitter layer 110 may comprise, for example, a boron-doped silicon layer or a phosphorus-doped silicon layer.

Subsequently, the rear side S2 of the substrate 100 may optionally be treated by chemical etching (Clean & Back side polish) to form a flat surface. A chemical vapor deposition process is then performed to form a tunnel oxide layer 120 and a doped semiconductor layer (e.g., an N-type doped silicon layer) 130 on the rear side S2 of the substrate 100.

According to an embodiment of the present invention, the tunnel oxide layer 120 comprises, for example, silicon dioxide, and its thickness is, for example, between 1-5 nanometers. According to an embodiment of the present invention, the doped semiconductor layer 130 may comprises for example, a polycrystalline silicon layer, a microcrystalline silicon layer, or an amorphous silicon layer. According to an embodiment of the present invention, the doped semiconductor layer 130 may have a single-layer or multi-layer material structure.

Next, as shown in FIG. 3, a laser activation treatment LP is performed on the doped semiconductor layer 130. For example, a laser with a wavelength such as 1064nm, 532nm, or 266nm and a power of 10W - 100W can be used. According to an embodiment of the present invention, after the laser activation treatment LP, at least one patterned low-resistivity region 130a is formed in the doped semiconductor layer 130.

According to an embodiment of the present invention, the doped semiconductor layer 130 further comprises at least one non-laser-activated region 130b adjacent to the at least one patterned low-resistivity region 130a. A resistivity value of the at least one patterned low-resistivity region 130a is lower than a resistivity value of the at least one non-laser-activated region 130b. Next, chemical etching for clean and wrap-around removal can be performed.

According to an embodiment of the present invention, after performing the laser activation treatment LP, a thermal annealing process, such as a low-temperature thermal annealing process below 600° C, may optionally be performed (this step may be omitted). The thermal annealing process can also be a thermal oxidation process, or a process involving other reactive gases, and is not limited to thermal treatment. Those skilled in the art should understand that the present invention does not limit the specific step in the cell production flow where the laser activation treatment LP is applied. For example, it can be applied before or after the clean and wrap-around removal process, or after the thermal annealing process. The present invention does not limit the steps or sequence of application.

As shown in FIG. 4, a front passivation layer 140 is then formed on the emitter layer 110. For example, front passivation layer 140 may comprise aluminum oxide (AlOₓ), but is not limited thereto. A chemical vapor deposition (CVD) process is then performed to form a front anti-reflection layer 150 on the front passivation layer 140. For example, the front anti-reflection layer 150 may comprise silicon nitride (SiNₓ) but is not limited thereto. A rear anti-reflection layer 160 is then formed on the doped semiconductor layer 130. For example, the rear anti-reflection layer 160 may comprise silicon nitride (SiNₓ) but is not limited thereto.

As shown in FIG. 5, a screen-printing process may be used to screen-print metal paste, such as silver paste, on the front anti-reflection layer 150 on the front side S1 of the substrate 100 to form a front metal electrode 210. Metal paste, such as silver paste, is then screen-printed on the rear anti-reflection layer 160 on the rear side S2 of the substrate 100 to form an electrode pattern 220. The electrode pattern 210 and the electrode pattern 220 may include busbar electrodes or finger electrodes (only the finger electrode is shown in the cross-section of this figure). According to an embodiment of the present invention, the front metal electrode 210 and the rear metal electrode 220 may comprise, for example, aluminum, silver, or an alloy thereof, but are not limited thereto.

Thereafter, a sintering process is performed, causing the front metal electrode 210 to penetrate through the front anti-reflection layer 150 and the front passivation layer 140 to contact the emitter layer 110, and causing the rear metal electrode 220 to penetrate through the rear anti-reflection layer 160 to directly contact the at least one patterned low-resistivity region 130a in the doped semiconductor layer 130, thereby completing the fabrication of the tunnel oxide passivated contact solar cell 1 of the present invention. According to an embodiment of the present invention, the at least one patterned low-resistivity region 130a is only formed directly under the rear metal electrode 220.

The present invention does not limit the area size of the at least one patterned low-resistivity region 130a. Generally, the at least one patterned low-resistivity region 130a should be larger than the area of the rear metal electrode 220 but is not limited thereto. For example, the region directly below the contact electrode 220 can be entirely or partially the at least one patterned low-resistivity region 130a. For example, the area below the finger electrode may be the at least one patterned low-resistivity region 130a, and the area below the busbar electrode may be the at least one non-laser-activated region 130b but is not limited thereto. Furthermore, the pattern of the at least one patterned low-resistivity region 130a is not limited, and it may be a continuous or non-continuous pattern. Additionally, the formation method of the at least one patterned low-resistivity region 130a is not limited. This embodiment illustrates the laser activation treatment LP but is not limited thereto.

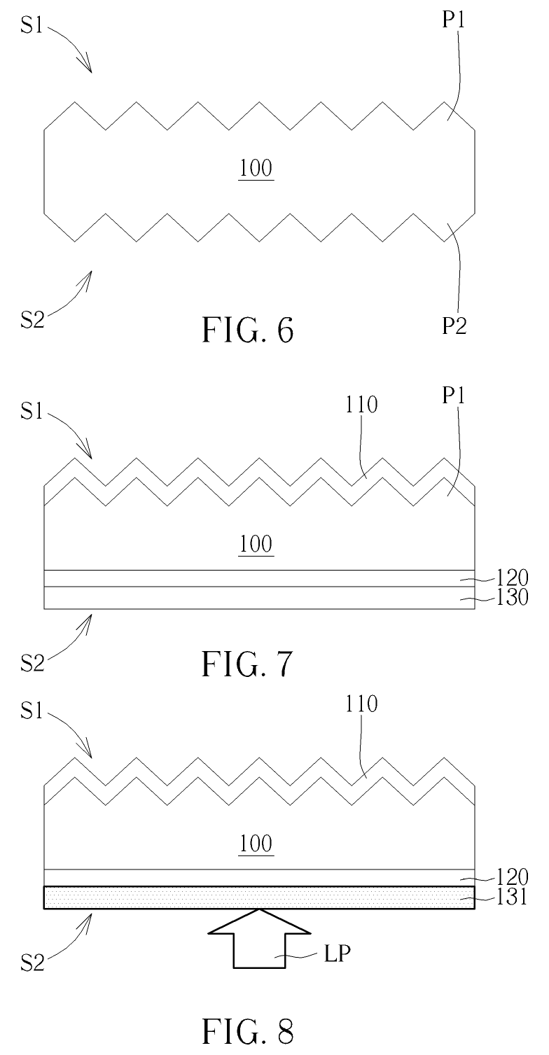

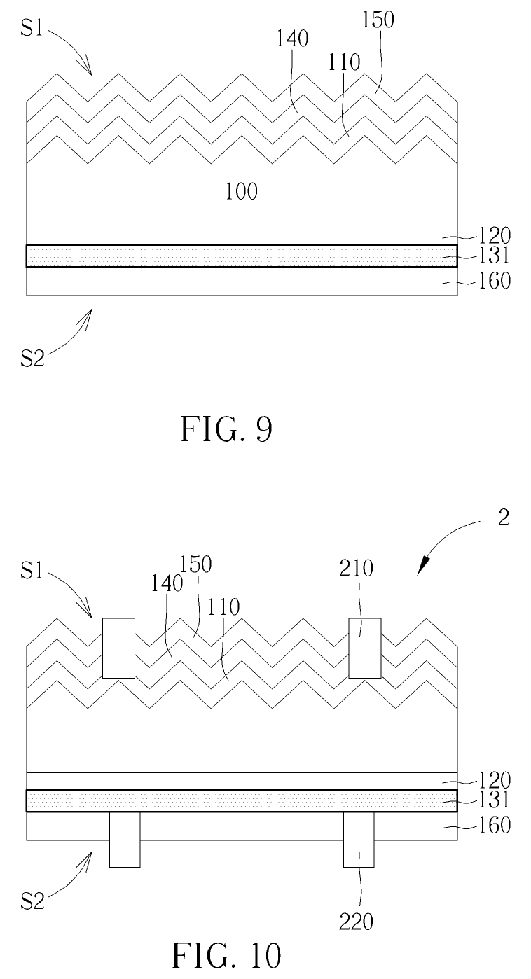

Please refer to FIGS. 6 - 10, which are schematic diagrams illustrating a method for fabricating a tunnel oxide passivated contact solar cell according to another embodiment of the present invention. As shown in FIG. 6, likewise, a substrate 100, such as a P-type silicon substrate or an N-type silicon substrate, is first provided. The wafer surface is then cleaned, and texturized structures P1 and P2 are respectively formed on the front side S1 and the rear side S2 of the substrate 100.

Next, as shown in FIG. 7, a boron diffusion process is performed to form an emitter layer 110 on the front side S1 of the substrate 100 (e.g., an N-type silicon substrate). According to an embodiment of the present invention, the emitter layer 110 is, for example, a boron-doped silicon layer or a phosphorus-doped silicon layer.

Then, the rear side S2 of the substrate 100 may optionally be treated by chemical etching (Clean & Back side polish) to form a flat surface. Subsequently, a chemical vapor deposition process is performed to form a tunnel oxide layer 120 and a doped semiconductor layer (e.g., an N-type doped silicon layer) 130 on the rear side S2 of the substrate 100.

According to an embodiment of the present invention, the tunnel oxide layer 120 may comprise, for example, silicon dioxide, and its thickness is, for example, between 1-5 nanometers. According to an embodiment of the present invention, the doped semiconductor layer 130 may comprise, for example, a polycrystalline silicon layer, a microcrystalline silicon layer, or an amorphous silicon layer.

Next, as shown in FIG. 8, a laser activation treatment LP is performed on the doped semiconductor layer 130. For example, a laser with a wavelength such as 1064nm, 532nm, or 266nm and a power of 10W- 100W can be used. According to another embodiment of the present invention, the laser activation treatment LP comprises converting the entire doped semiconductor layer 130 into a low-resistivity layer 131 using a laser.

Next, chemical etching for clean and wrap-around removal can be performed. According to an embodiment of the present invention, after performing the laser activation treatment LP, a thermal annealing process, such as a low-temperature thermal annealing process below 600° C, may optionally be performed (this step may be omitted). The thermal annealing process can also be a thermal oxidation process, or a process involving other reactive gases, and is not limited to thermal treatment. Those skilled in the art should understand that the present invention does not limit the specific step in the cell production flow where the laser activation treatment LP is applied. For example, it can be applied before or after the clean and wrap-around removal process, or after the thermal annealing process. The present invention does not limit the steps or sequence of application.

As shown in FIG. 9, a front passivation layer 140 is then formed on the emitter layer 110. For example, the front passivation layer 140 may comprise aluminum oxide (AlOₓ, but is not limited thereto. A chemical vapor deposition process is then performed to form a front anti-reflection layer 150 on the front passivation layer 140. For example, the front anti-reflection layer 150 may comprise silicon nitride (SiNₓ) but is not limited thereto. A rear anti-reflection layer 160 is then formed on the low-resistivity layer 131. For example, the rear anti-reflection layer 160 may comprise silicon nitride (SiNₓ) but is not limited thereto.

As shown in FIG. 10, a screen-printing process may be used to screen-print metal paste, such as silver paste, on the front anti-reflection layer 150 on the front side S1 of the substrate 100 to form a front metal electrode 210. Metal paste, such as silver paste, is then screen-printed on the rear anti-reflection layer 160 on the rear side S2 of the substrate 100 to form an electrode pattern 220. The electrode pattern 210 and the electrode pattern 220 may include busbar electrodes or finger electrodes (only the finger electrode is shown in the cross-section of this figure). According to an embodiment of the present invention, the front metal electrode 210 and the rear metal electrode 220 may comprise, for example, aluminum, silver, or an alloy thereof, but are not limited thereto.

Thereafter, a sintering process is performed, causing the front metal electrode 210 to penetrate through the front anti-reflection layer 150 and the front passivation layer 140 to contact the emitter layer 110, and causing the rear metal electrode 220 to penetrate through the rear anti-reflection layer 160 to directly contact the low-resistivity layer 131, thereby completing the fabrication of the tunnel oxide passivated contact solar cell 2 of the present invention.

Structurally, as shown in FIG. 5, the tunnel oxide passivated contact solar cell 1 of the present invention comprises: the substrate 100; the emitter layer 110 disposed on the front side S1 of the substrate 100; the front passivation layer 140 disposed on the emitter layer 110; the front anti-reflection layer 150 disposed on the front passivation layer 140; the front metal electrode 210 penetrating through the front anti-reflection layer 150 and the front passivation layer 140, contacting the emitter layer 110; the tunnel oxide layer 120 disposed on the rear side S2 of the substrate 100; the laser-activated doped semiconductor layer 130 disposed on the tunnel oxide layer 120; the rear anti-reflection layer 160 disposed on the laser-activated doped semiconductor layer 130; and the rear metal electrode 220 penetrating through the rear anti-reflection layer 160, directly contacting the laser-activated doped semiconductor layer 130.

According to an embodiment of the present invention, the laser-activated doped semiconductor layer 130 comprises at least one patterned low-resistivity region 130a, and the at least one patterned low-resistivity region 130a is disposed directly under the rear metal electrode 220. According to an embodiment of the present invention, the at least one patterned low-resistivity region 130a is a laser-activated patterned region.

According to an embodiment of the present invention, the laser-activated doped semiconductor layer 130 further comprises at least one non-laser-activated region 130b. A resistivity value of the at least one patterned low-resistivity region 130a is lower than a resistivity value of the at least one non-laser-activated region 130b.

According to an embodiment of the present invention, the substrate 100 comprises, for example, a P-type silicon substrate or an N-type silicon substrate. According to an embodiment of the present invention, the emitter layer 110 comprises, for example, a boron-doped silicon layer or a phosphorus-doped silicon layer. According to an embodiment of the present invention, the tunnel oxide layer 120 comprises, for example, silicon dioxide, and its thickness is between 1-5 nanometers.

According to an embodiment of the present invention, the laser-activated doped semiconductor layer 130 comprises an N-type polycrystalline silicon layer, and the rear anti-reflection layer 160 comprises silicon nitride. According to an embodiment of the present invention, the front metal electrode 210 and the rear metal electrode 220 comprise aluminum, silver, or an alloy thereof.

According to another embodiment of the present invention, as shown in FIG. 10, the entire laser-activated doped semiconductor layer 130 is the laser-activated low-resistivity layer 131.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A tunnel oxide passivated contact solar cell, comprising:
a substrate having a front side and a rear side;
an emitter layer disposed on the front side of the substrate;
a front passivation layer disposed on the emitter layer;
a front anti-reflection layer disposed on the front passivation layer;
a front metal electrode penetrating through the front anti-reflection layer and the front passivation layer, contacting the emitter layer;
a tunnel oxide layer disposed on the rear side of the substrate;
a laser-activated doped semiconductor layer disposed on the tunnel oxide layer;
a rear anti-reflection layer disposed on the laser-activated doped semiconductor layer; and
a rear metal electrode penetrating through the rear anti-reflection layer, directly contacting the laser-activated doped semiconductor layer.

2. The tunnel oxide passivated contact solar cell according to claim 1, wherein the laser-activated doped semiconductor layer comprises at least one patterned low-resistivity region, and the at least one patterned low-resistivity region is disposed directly under the rear metal electrode.

3. The. tunnel oxide passivated contact solar cell according to claim 2, wherein the at least one patterned low-resistivity region is a laser-activated patterned region.

4. The tunnel oxide passivated contact solar cell according to claim 3, wherein the laser-activated doped semiconductor layer further comprises at least one non-laser-activated region adjacent to the laser-activated patterned region, and a resistivity value of the laser-activated patterned region is lower than a resistivity value of the at least one non-laser-activated region.

5. The tunnel oxide passivated contact solar cell according to claim 1, wherein the substrate comprises a P-type silicon substrate or an N-type silicon substrate.

6. The tunnel oxide passivated contact solar cell according to claim 1, wherein the emitter layer comprises a boron-doped silicon layer or a phosphorus-doped silicon layer.

7. The tunnel oxide passivated contact solar cell according to claim 1, wherein the tunnel oxide layer comprises silicon dioxide.

8. The tunnel oxide passivated contact solar cell according to claim 1, wherein entire said laser-activated doped semiconductor layer is a laser-activated low-resistivity layer.

9. The tunnel oxide passivated contact solar cell according to claim 1, wherein the laser-activated doped semiconductor layer comprises an N-type polycrystalline silicon layer.

10. The tunnel oxide passivated contact solar cell according to claim 1, wherein the front metal electrode and the rear metal electrode comprise aluminum, silver, or an alloy thereof.

11. A method for fabricating a tunnel oxide passivated contact solar cell, comprising:
providing a substrate having a front side and a rear side;
forming an emitter layer on the front side of the substrate;
forming a tunnel oxide layer on the rear side of the substrate;
forming a doped semiconductor layer on the tunnel oxide layer;
performing a laser activation treatment on the doped semiconductor layer;
forming a front passivation layer on the emitter layer;
forming a front anti-reflection layer on the front passivation layer;
forming a rear anti-reflection layer on the doped semiconductor layer;
forming a front metal electrode penetrating through the front anti-reflection layer and the front passivation layer, contacting the emitter layer; and
forming a rear metal electrode penetrating through the rear anti-reflection layer, directly contacting the doped semiconductor layer.

12. The method for fabricating a tunnel oxide passivated contact solar cell according to claim 11, wherein said performing the laser activation treatment on the doped semiconductor layer comprises forming at least one patterned low-resistivity region in the doped semiconductor layer.

13. The method for fabricating a tunnel oxide passivated contact solar cell according to claim 12, wherein the at least one patterned low-resistivity region is only formed directly under the rear metal electrode, and wherein the doped semiconductor layer further comprises at least one non-laser-activated region adjacent to the at least one patterned low-resistivity region, and a resistivity value of the at least one patterned low-resistivity region is lower than a resistivity value of the at least one non-laser-activated region.

14. The method for fabricating a tunnel oxide passivated contact solar cell according to claim 11, wherein said performing the laser activation treatment on the doped semiconductor layer comprises converting the entire doped semiconductor layer into a low-resistivity layer using a laser.

15. The method for fabricating a tunnel oxide passivated contact solar cell according to claim 11, further comprising a thermal annealing process after performing the laser activation treatment on the doped semiconductor layer.

16. The method for fabricating a tunnel oxide passivated contact solar cell according to claim 11, wherein the doped semiconductor layer comprises a polycrystalline semiconductor layer, a microcrystalline semiconductor layer, or an amorphous semiconductor layer.

17. The method for fabricating a tunnel oxide passivated contact solar cell according to claim 11, wherein the substrate comprises a P-type silicon substrate or an N-type silicon substrate.

18. The method for fabricating a tunnel oxide passivated contact solar cell according to claim 11, wherein the emitter layer comprises a boron-doped silicon layer or a phosphorus-doped silicon layer.

19. The method for fabricating a tunnel oxide passivated contact solar cell according to claim 11, wherein the tunnel oxide layer comprises silicon dioxide.

20. The method for fabricating a tunnel oxide passivated contact solar cell according to claim 11, wherein the front metal electrode and the rear metal electrode comprise aluminum, silver, or an alloy thereof.
